(19) United States
(12) Patent Application Publication
(10) Pub. No.: US 2014/0043896 A1
(43) Pub. Date: Feb. 13, 2014

(54) METHOD OF PREVENTING PROGRAM-DISTURBANCES FOR A NON-VOLATILE SEMICONDUCTOR MEMORY DEVICE

(71) Applicant: Samsung Electronics Co., Ltd., Suwon-si (KR)

(72) Inventors: Weon-Ho Park, Hwaseong-si (KR); Hyok-Ki Kwon, Hwaseong-si (KR); Min-Sup Kim, Seoul (KR); Min-Su Kim, Seongnam-si (KR); Byoung-Ho Kim, Suwon-si (KR); Eui-Yeol Kim, Yongin-si (KR); Sang-Hoon Park, Hwaseong-si (KR); Ji-Hoon Park, Seongnam-si (KR); Min-Jee Sung, Suwon-si (KR); Hyo-Soung Sim, Hwaseong-si (KR); Chang-Min Jeon, Yongin-si (KR); Hee-Seog Jeon, Suwon-si (KR)

(21) Appl. No.: 13/939,611

(22) Filed: Jul. 11, 2013

(30) Foreign Application Priority Data
Aug. 8, 2012 (KR) 10-2012-0086852

(51) Int. Cl. G11C 16/34

(52) U.S. Cl. CPC G11C 16/3431
USPC 365/185.02; 365/185.18

(57) ABSTRACT

A method of preventing program-disturbances for a non-volatile semiconductor memory device having a plurality of memory cells of which each includes a selection transistor and a memory transistor coupled in series between a bit-line and a common source-line is provided. First non-selected memory cells that share a first selection-line with a selected memory cell, and second non-selected memory cells that do not share the first selection-line with the selected memory cell are determined when the selected memory cell is selected to be programmed among the memory cells. A negative voltage is applied to second selection-lines that are coupled to the second non-selected memory cells when the selected memory cell is programmed by applying a positive voltage to the first selection-line that is coupled to the selected memory cell.

### CROSS-REFERENCE TO RELATED APPLICATION(S)

This application claims priority under 35 USC §119 to Korean Patent Application No. 10-2012-0086852, filed on Aug. 8, 2012 in the Korean Intellectual Property Office (KIPO), the contents of which are incorporated herein in its entirety by reference.

### BACKGROUND

1. Technical Field

Example embodiments relate generally to a non-volatile semiconductor memory device. More particularly, embodiments of the inventive concepts relate to a method of preventing program-disturbances for a non-volatile semiconductor memory device.

2. Description of the Related Art

Semiconductor memory devices may generally be classified into two types: volatile semiconductor memory devices in which data are erased when a power is removed and a non-volatile semiconductor memory device in which data are preserved even in a case where power is removed. Generally, non-volatile semiconductor memory devices have relatively slow read-speed and a relatively slow write-speed as compared to volatile semiconductor memory devices. However, non-volatile semiconductor memory devices enjoy widespread use in situations requiring data retention when power is removed and even in cases when power is in continuing supply.

An electrically erasable programmable read-only memory (EEPROM) device has become widely used as the non-volatile semiconductor memory device. Typically, the EEPROM device performs a program-operation in a byte unit, and performs an erase-operation in a block unit or in a sector unit. Recently, a 2T-FN (i.e., 2 transistors Fowler-Nordheim) type EEPROM device has been suggested as a flash memory device that performs an erase-operation in a byte unit.

The 2T-FN type EEPROM device includes a memory cell having 2 transistors, and performs a program-operation and an erase-operation using an F-N (i.e., Fowler-Nordheim) tunneling phenomenon. Here, 2 transistors of the memory cell included in the 2T-FN type EEPROM device are coupled to each other in series. In detail, one transistor of the memory cell included in the 2T-FN type EEPROM device operates as a memory transistor (e.g., floating gate tunnel oxide (FLOTOX) memory transistor). In addition, another transistor of the memory cell included in the 2T-FN type EEPROM device operates as a selection transistor.

When the 2T-FN type EEPROM device performs a program-operation, a specific voltage bias condition may be applied to a selected memory cell to result in the occurrence of the F-N tunneling phenomenon in the memory transistor. As a result, data may be stored by accumulating electrons in a floating gate. However, in some situations when a program-operation is performed, neighboring non-selected memory cells may be simultaneously programmed (i.e., referred to as program-disturbance). Such program-disturbance can degrade reliability of the 2T-FN type EEPROM device.

### SUMMARY

Some example embodiments provide a method of preventing program-disturbances for a non-volatile semiconductor memory device capable of preventing non-selected memory cells from being programmed when a selected memory cell is programmed in the non-volatile semiconductor memory device, where the non-selected memory cells do not share a selection-line with the selected memory cell.

According to some example embodiments, a method of preventing program-disturbances for a non-volatile semiconductor memory device having a plurality of memory cells, each memory cell in including a selection transistor and a memory transistor that are coupled in series between a bit-line and a common source-line, where a gate terminal of the selection transistor is coupled to a word-line and a gate terminal of the memory transistor is coupled to a selection-line, is provided. First non-selected memory cells that share a first selection-line with a selected memory cell, and second non-selected memory cells that do not share the first selection-line with the selected memory cell may be determined when the selected memory cell is selected to be programmed among the memory cells. A negative voltage may be applied to second selection-lines that are coupled to the second non-selected memory cells when the selected memory cell is programmed by applying a positive voltage to the first selection-line that is coupled to the selected memory cell.

In example embodiments, common source-lines that are coupled to the selected memory cell, the first non-selected memory cells, and the second non-selected memory cells may be floated when the selected memory cell is programmed.

In example embodiments, a negative voltage that is between about −2V and −10V may be applied to a pocket P-well in which the selected memory cell, the first non-selected memory cells, and the second non-selected memory cells are located when the selected memory cell is programmed.

In example embodiments, a negative voltage of about −6V may be applied to the pocket P-well in which the selected memory cell, the first non-selected memory cells, and the second non-selected memory cells are located when the selected memory cell is programmed.

In example embodiments, a positive voltage that is between about 6V and about 14V may be applied to a deep N-well that is formed under the pocket P-well when the selected memory cell is programmed.

In example embodiments, a positive voltage of about 10V may be applied to the deep N-well that is formed under the pocket P-well when the selected memory cell is programmed.

In example embodiments, a negative voltage that is between about −2V and about −10V may be applied to word-lines that are coupled to the selected memory cell, the first non-selected memory cells, and the second non-selected memory cells when the selected memory cell is programmed.

In example embodiments, a negative voltage of about −6V may be applied to the word-lines that are coupled to the selected memory cell, the first non-selected memory cells, and the second non-selected memory cells when the selected memory cell is programmed.

In example embodiments, the negative voltage that is applied to the second selection-lines may be determined to be between about −1V and about −3V when the selected memory cell is programmed.

In example embodiments, the negative voltage that is applied to the second selection-lines may be determined to be about −2V when the selected memory cell is programmed.

In example embodiments, the positive voltage that is applied to the first selection-line may be determined to be between about 6V and about 14V when the selected memory cell is programmed.

In example embodiments, the positive voltage that is applied to the first selection-line may be determined to be about 10V when the selected memory cell is programmed.

In example embodiments, a negative voltage that is between about −2V and about −10V may be applied to a first bit-line that is coupled to the selected memory cell when the selected memory cell is programmed.

In example embodiments, a negative voltage of about −6V may be applied to the first bit-line that is coupled to the selected memory cell when the selected memory cell is programmed.

In example embodiments, the program-disturbances due to an F-N tunneling phenomenon may be prevented in the second non-selected memory cells that share the first bit-line with the selected memory cell when the selected memory cell is programmed.

In example embodiments, the program-disturbances due to an electron-hole pair phenomenon may be prevented in the second non-selected memory cells that do not share the first bit-line with the selected memory cell when the selected memory cell is programmed.

In another example embodiment in a method of programming a non-volatile memory device, the device includes a plurality of memory cells, each memory cell including a selection transistor and memory transistor arranged in series between a bit line and a common source line of the memory device, a gate terminal of the selection transistor being coupled to a word line of the device and a gate terminal of the memory transistor being coupled to a selection line of the device. During a programming operation of a selected memory cell by applying a positive voltage to a first selection line that is coupled to the selected memory cell, a negative bias condition is applied to non-selected memory cells by applying a negative voltage to second selection lines that are respectively coupled to the non-selected memory cells.

In some embodiments, non-selected memory cells are associated with a same bit line as the selected memory cell.

In some embodiments, the method further comprises applying a negative voltage to the bit line that is associated with the selected memory cell, and applying a GND voltage to bit lines that are unassociated with the selected memory cell.

In some embodiments, the negative voltage is in a range between about −1V and about −3V.

In some embodiments, the negative voltage is about −2V.

Therefore, a method of preventing program-disturbances for a non-volatile semiconductor memory device according to example embodiments may apply a negative bias condition to non-selected memory cells, for example a negative voltage can be applied to selection-lines coupled to the non-selected memory cells, where the non-selected memory cells do not share a selection-line with a selected memory cell, when the selected memory cell is programmed in the non-volatile semiconductor memory device. Thus, the non-selected memory cells may be prevented from becoming inadvertently programmed when the selected memory cell is programmed. As a result, reliability of the non-volatile semiconductor memory device may be greatly improved.

### BRIEF DESCRIPTION OF THE DRAWINGS

Illustrative, non-limiting example embodiments will be more clearly understood from the following detailed description taken in conjunction with the accompanying drawings.

FIG. 1 is a flow diagram illustrating a method of preventing program-disturbances for a non-volatile semiconductor memory device according to example embodiments.

FIG. 2 is a diagram illustrating an embodiment of a memory cell array to which a method of FIG. 1 is applied.

FIG. 3 is a cross-sectional diagram illustrating a memory cell included in a memory cell array of FIG. 2.

FIG. 4 is a diagram illustrating a voltage bias condition for a selected memory cell in the method of FIG. 1.

FIGS. 5A and 5B are diagrams illustrating a voltage bias condition for a second non-selected memory cell in the method of FIG. 1.

FIG. 6 is a diagram illustrating a voltage bias condition for a first non-selected memory cell in the method of FIG. 1.

FIG. 7 is a block diagram illustrating an embodiment of a non-volatile semiconductor memory device employing the method of FIG. 1.

FIG. 8 is a block diagram illustrating a memory system having a device of FIG. 7.

FIG. 9 is a diagram illustrating an example in which a host device is coupled to the device of FIG. 7.

FIG. 10 is a diagram illustrating another example in which a host device is coupled to the device of FIG. 7.

FIG. 11 is a diagram illustrating still another example in which a host device is coupled to the device of FIG. 7.

FIG. 12 is a block diagram illustrating an electronic device including the device of FIG. 7.

### DETAILED DESCRIPTION OF THE EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this disclosure will be thorough and complete, and will fully convey the scope of the present inventive concepts to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concepts. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

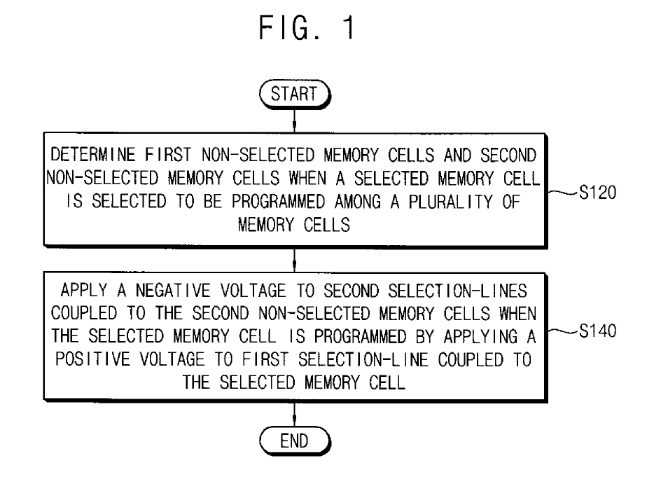

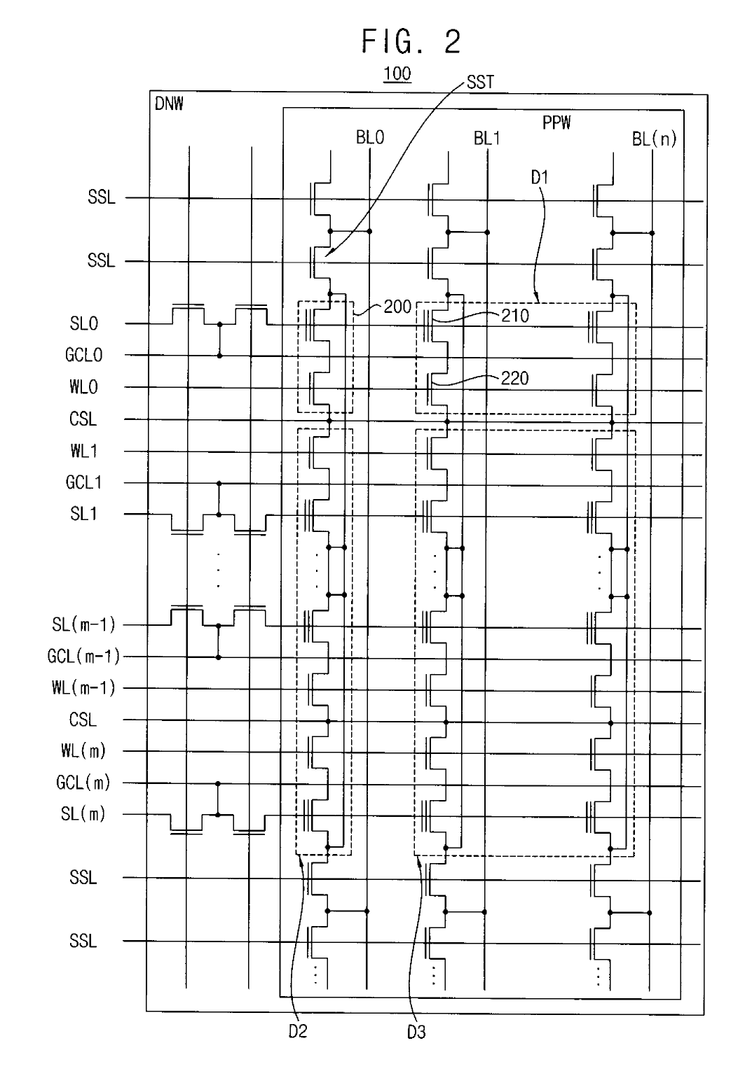

FIG. 1 is a flow diagram illustrating a method of preventing program-disturbances for a non-volatile semiconductor memory device according to example embodiments. FIG. 2 is a diagram illustrating a memory cell array to which a method of FIG. 1 is applied. FIG. 3 is a cross-sectional diagram illustrating a memory cell included in a memory cell array of FIG. 2.

Referring to FIGS. 1 through 3, it is illustrated that a non-volatile semiconductor memory device includes a plurality of memory cells 200 of which each has a selection transistor 220 and a memory transistor 210. Here, the selection transistor 220 and the memory transistor 210 are coupled in series between a bit-line BL and a common source-line CSL. In addition, a gate terminal of the selection transistor 220 is coupled to a word-line WL, and a gate terminal of the memory transistor 210 is coupled to a selection-line SL. In example embodiments, a direction of the bit-line BL is illustrated as being generally perpendicular to the word-line WL and the selection-line SL. The method illustrated in connection with FIG. 1 may be operative to determine first non-selected memory cells that share a first selection-line with a selected memory cell, and second non-selected memory cells that do not share the first selection-line with the selected memory cell (Step S120) when a selected memory cell is selected to be programmed among the memory cells 200. Subsequently, the method of FIG. 1 may apply a negative voltage to second selection-lines that are coupled to the second non-selected memory cells (Step S140) when the selected memory cell is programmed by applying a positive voltage to the first selection-line that is coupled to the selected memory cell. Here, the first selection-line is distinguished from the second selection-lines. That is, the first selection-line indicates the selection-line SL that is coupled to the selected memory cell and the first non-selected memory cells, and the second selection-lines indicate the selection-lines SL that are coupled to the second non-selected memory cells.

In FIG. 2, a memory cell array 100 of the non-volatile semiconductor memory device is illustrated. As illustrated in FIG. 2, the memory cell array 100 may include a plurality of memory cells 200. Each memory cell 200 may include two transistors (i.e., the memory transistor 210 and the selection transistor 220). Here, the memory transistor 210 may be operative to store data, and the selection transistor 220 may be operative to select the memory transistor 210. In some embodiments, the memory transistor 210 and the selection transistor 220 may be coupled in series between the bit-line BL and the common source-line CSL, in the manner shown in FIG. 2. In the memory cell array 100, a plurality of word-lines WL0 through WL(m) may be arranged in a row direction, a plurality of bit-lines BL0 through BL(n) may be arranged in a column direction, a plurality of selection-lines SL0 through SL(m) may be arranged in the row direction, and a plurality of common source-lines CSL may be arranged in the row direction. Here, a gate terminal of the memory transistor 210 may be coupled to the selection-line SL, and a gate terminal of the selection transistor 220 may be coupled to the word-line WL. Thus, a plurality of memory transistors 210 that are arranged in the same row may be coupled to the same selection-line SL, and a plurality of selection transistors 220 that are arranged in the same row may be coupled to the same word-line WL. In addition, a first terminal of the memory transistor 210 may be coupled to the bit-line BL, a second terminal of the selection transistor 220 may be coupled to the common source-line CSL, and a second terminal of the memory transistor 210 may be coupled to a first terminal of the selection transistor 220. According to some example embodiments, the common source-line CSL may be arranged in each row, in each column, or in each sector of the memory device.

The memory cell array 100 may include a plurality of blocks corresponding to a plurality of pocket P-wells PPW in a deep N-well DNW. Here, one block may include a plurality of sectors each having a plurality of memory cells 200. For the convenience of description, only one sector among a plurality of sectors in one block is illustrated in FIG. 2. Each sector may be selected by a sector selection transistor SST. Here, the sector selection transistor SST may be controlled by a voltage that is applied to a sector selection-line SSL. The sector selection transistor SST may define a plurality of memory cells 200 corresponding to one sector. That is, the sector selection transistor SST may select one sector (i.e., a plurality of memory cells 200 coupled in series between sector selection transistors SST) among a plurality of sectors that are formed in a pocket P-well PPW (i.e., a block) for operation. Here, as illustrated in FIG. 2, a plurality of memory cells 200 corresponding to one sector may share the same bit-line BL. When a bias selection transistor turns-on, a voltage that is applied to a global control-line GCL may be simultaneously applied to a plurality of memory cells 200 that are arranged in the same row through the selection-line SL. In addition, a voltage that is applied to the word-line WL may be simultaneously applied to a plurality of memory cells 200 that are arranged in the same row. Since one memory cell 200 is coupled to other memory cells 200 in a row direction and in a column direction, other memory cells 200 may be softly programmed, for example, as a result of program-disturbance, when one of the memory cells 200 is programmed from an on-state to an off-state.

FIG. 3 illustrates one of the memory cells 200 included in the memory cell array 100. As illustrated in FIG. 3, the memory cell 200 may be formed in a pocket P-well 230 that is located in a deep N-well 240 of a P-type semiconductor substrate 250. In other words, the memory transistor 210 and the selection transistor 220 of the memory cell 200 may be formed in the pocket P-well 230 that is located in the deep N-well 240 of the P-type semiconductor substrate 250. A gate terminal of the memory transistor 210 may include a gate insulating layer 211, a floating gate 212, a gate insulating layer 213, and a control gate 214 that are sequentially formed on the pocket P-well 230. Here, the gate insulating layer 211 may include a tunneling region having a relatively thin thickness. In the tunneling region, the F-N tunneling phenomenon may occur when the memory cell 200 is programmed or erased. As a result, charge may be transported or moved to the floating gate 212 through the tunneling region. According to example embodiments, as illustrated in FIG. 3, a gate terminal of the selection transistor 220 may have a similar structure to that of the gate terminal of the memory transistor 210. However, the F-N tunneling phenomenon may not occur in the selection transistor 220. For this reason, the gate terminal of the selection transistor 220 may have a structure having a gate insulating layer and a selection gate that are sequentially formed on the pocket P-well 230. The gate terminal of the memory transistor 210 may be coupled to the selection-line SL, and a first terminal of the memory transistor 210 (i.e., n+ doping region 231 corresponding to the first terminal of the memory transistor 210) may be coupled to the bit-line BL. A gate terminal of the selection transistor 220 may be coupled to the word-line WL, and a second terminal of the selection transistor 220 (i.e., n+ doping region 233 corresponding to the second terminal of the selection transistor 220) may be coupled to the common source-line CSL. In addition, a second terminal of the memory transistor 210 (i.e., n+ doping region 232 corresponding to the second terminal of the memory transistor 210) may be coupled to a first terminal of the selection transistor 220 (i.e., n+ doping region 232 corresponding to the first terminal of the selection transistor 220).

Based on the structure illustrated in FIGS. 2 and 3, the method of FIG. 1 may be operative to determine first non-selected memory cells that share the first selection-line with the selected memory cell, and the second non-selected memory cells that do not share the first selection-line with the selected memory cell (Step S120) when the selected memory cell is selected to be programmed among the memory cells 200. To program the selected memory cell from an on-state to an off-state, the method of FIG. 1 may be operative to float the common source-line CSL coupled to the selected memory cell, may apply a negative voltage (e.g., between −2V and −10V) to the pocket P-well PPW in which the selected memory cell is located, and may apply a positive voltage (e.g., between 6V and 14V) to the deep N-well DNW in which the selected memory cell is located. In one example embodiment, a negative voltage of −6V may be applied to the pocket P-well PPW in which the selected memory cell is located, and a positive voltage of 10V may be applied to the deep N-well DNW in which the selected memory cell is located. In addition, in the method of FIG. 1 a negative voltage (e.g., between −2V and −10V) may be applied to the word-line WL coupled to the selected memory cell, may apply a positive voltage (e.g., between 6V and 14V) to the first selection-line coupled to the selected memory cell, and may apply a negative voltage (e.g., between −2V and −10V) to the bit-line BL coupled to the selected memory cell. In one example embodiment, a negative voltage of −6V may be applied to the word-line WL coupled to the selected memory cell, a positive voltage of 10V may be applied to the first selection-line coupled to the selected memory cell, and a negative voltage of −6V may be applied to the bit-line BL coupled to the selected memory cell. As a result, the selected memory cell may be programmed because charge is injected into the selected memory cell in accordance with the F-N tunneling phenomenon (i.e., electrons are accumulated in the floating gate 212 of the selected memory cell by a voltage difference between the first selection-line and the bit-line BL).

In addition, operation of the method of FIG. 1 may prevent the second non-selected memory cells from being programmed (i.e., may prevent the program-disturbances), where the second non-selected memory cells do not share the first selection-line with the selected memory cell, by applying a negative bias condition to the second non-selected memory cells. Assuming that the memory cell 200 is the selected memory cell in FIG. 2, the non-selected memory cells may be considered to be divided into the first non-selected memory cells that share the first selection-line with the selected memory cell, and the second non-selected memory cells that do not share the first selection-line with the selected memory cell. The first non-selected memory cells are located in a first region D1. In addition, the second non-selected memory cells may be divided into the second non-selected memory cells that are located in a second region D2, and the second non-selected memory cells that are located in a third region D3. As illustrated in FIG. 2, the first non-selected memory cells of the first region D1 share the first selection-line with the selected memory cell. Thus, the first non-selected memory cells of the first region D1 may be located in the same row as the selected memory cell. In addition, the second non-selected memory cells of the second region D2 share the bit-line with the selected memory cell. Thus, the second non-selected memory cells of the second region D2 may be located in the same column as the selected memory cell. Further, the second non-selected memory cells of the third region D3 may be located in a different row and column from those of the selected memory cell. Here, the method of FIG. 1 may program the selected memory cell by applying a positive voltage to the first selection-line coupled to the selected memory cell. Meantime, operation of the method of FIG. 1 may prevent the second non-selected memory cells from being programmed by applying a negative voltage to the second selection-lines coupled to the second non-selected memory cells, where the first selection-line is distinguished from the second selection-lines (Step S140).

In detail, the method of FIG. 1 may be operative to place in a floating condition the common source-line CSL coupled to the second non-selected memory cells of the second region D2, may apply a negative voltage (e.g., between −2V and −10V) to the pocket P-well PPW in which the second non-selected memory cells of the second region D2 are located, and may apply a positive voltage (e.g., between 6V and 14V) to the deep N-well DNW in which the second non-selected memory cells of the second region D2 are located. In one example embodiment, a negative voltage of −6V may be applied to the pocket P-well PPW in which the second non-selected memory cells of the second region D2 are located, and a positive voltage of 10V may be applied to the deep N-well DNW in which the second non-selected memory cells of the second region D2 are located. In addition, the method of FIG. 1 may apply a negative voltage (e.g., between −2V and −10V) to the word-line WL coupled to the second non-selected memory cells of the second region D2, may apply a negative voltage (e.g., between −1V and −3V) to the second selection-line coupled to the second non-selected memory cells of the second region D2, and may apply a negative voltage (e.g., between −2V and −10V) to the bit-line BL coupled to the second non-selected memory cells of the second region D2. In one example embodiment, a negative voltage of −6V may be applied to the word-line WL coupled to the second non-selected memory cells of the second region D2, a negative voltage of −2V may be applied to the second selection-line coupled to the second non-selected memory cells of the second region D2, and a negative voltage of −6V may be applied to the bit-line BL coupled to the second non-selected memory cells of the second region D2. As described above, since the second non-selected memory cells of the second region D2 share the bit-line BL with the selected memory cell, the second non-selected memory cells of the second region D2 may receive a negative voltage (e.g., between −2V and −10V) through the bit-line BL. However, since a negative voltage (e.g., between −1V and −3V) is applied to the second selection-line coupled to the second non-selected memory cells of the second region D2, charge injection due to the F-N tunneling phenomenon may be mitigated or prevented in the second non-selected memory cells of the second region D2.

The method of FIG. 1 may float the common source-line CSL coupled to the second non-selected memory cells of the third region D3, may apply a negative voltage (e.g., between −2V and −10V) to the pocket P-well PPW in which the second non-selected memory cells of the third region D3 are located, and may apply a positive voltage (e.g., between 6V and 14V) to the deep N-well DNW in which the second non-selected memory cells of the third region D3 are located. In one example embodiment, a negative voltage of −6V may be applied to the pocket P-well PPW in which the second non-selected memory cells of the third region D3 are located, and a positive voltage of 10V may be applied to the deep N-well DNW in which the second non-selected memory cells of the third region D3 are located. In addition, the method of FIG. 1 may apply a negative voltage (e.g., between −2V and −10V) to the word-line WL coupled to the second non-selected memory cells of the third region D3, may apply a negative voltage (e.g., between −1V and −3V) to the second selection-line coupled to the second non-selected memory cells of the third region D3, and may apply a ground voltage (e.g., 0V) to the bit-line BL coupled to the second non-selected memory cells of the third region D3. In one example embodiment, a negative voltage of −6V may be applied to the word-line WL coupled to the second non-selected memory cells of the third region D3, and a negative voltage of −2V may be applied to the second selection-line coupled to the second non-selected memory cells of the third region D3. As described above, since a negative voltage (e.g., between −1V and −3V) is applied to the second selection-line coupled to the second non-selected memory cells of the third region D3, charge injection due to an electron-hole pair phenomenon may be mitigated or prevented in the second non-selected memory cells of the third region D3.

The method of FIG. 1 may prevent the program-disturbances in the first non-selected memory cells, where the first non-selected memory cells share the first selection-line with the selected memory cell, by applying a ground voltage to the bit-line BL coupled to the first non-selected memory cells of the first region D1. Assuming that the memory cell 200 is the selected memory cell in FIG. 2, the first non-selected memory cells are located in the first region D1. Thus, the first non-selected memory cells shares the first selection-line with the selected memory cell. That is, the first non-selected memory cells of the first region D1 may be located in the same row as the selected memory cell. As a result, the common source-line CSL coupled to the first non-selected memory cells of the first region D1 may be floated. In addition, a negative voltage (e.g., between −2V and −10V) may be applied to the pocket P-well PPW in which the first non-selected memory cells of the first region D1 are located, a positive voltage (e.g., between 6V and 14V) may be applied to the deep N-well DNW in which the first non-selected memory cells of the first region D1, a negative voltage (e.g., between −2V and −10V) may be applied to the word-line WL coupled to the first non-selected memory cells of the first region D1, and a positive voltage (e.g., between 6V and 14V) may be applied to the first selection-line coupled to the first non-selected memory cells of the first region D1. In one example embodiment, a negative voltage of −6V may be applied to the pocket P-well PPW in which the first non-selected memory cells of the first region D1 are located, a positive voltage of 10V may be applied to the deep N-well DNW in which the first non-selected memory cells of the first region D1 are located, a negative voltage of −6V may be applied to the word-line WL coupled to the first non-selected memory cells of the first region D1, and a positive voltage of 10V may be applied to the first selection-line coupled to the first non-selected memory cells of the first region D1. However, since a ground voltage is applied to the bit-line BL coupled to the first non-selected memory cells of the first region D1, a voltage difference between the first selection-line and the bit-line BL is relatively small in the first non-selected memory cells of the first region D1. Thus, charge may not be accumulated in the floating gate 212 of each first non-selected memory cell of the first region D1. As a result, the first non-selected memory cells of the first region D1 may not be programmed.

Generally, the frequency of program-disturbances is increased in accordance with an increase in the number of times the device has been programmed. As a result, such program-disturbances may degrade reliability of the non-volatile semiconductor memory device. For example, when data to be stored in the non-volatile semiconductor memory device are code-data, the number of times being programmed is relatively small due to characteristics of the code-data. Thus, the number of program-disturbances can be relatively small when the code-data are stored. However, when data to be stored in the non-volatile semiconductor memory device are operation-data, the number of times the cells are to be programmed is relatively great due to characteristics of the operation-data. Thus, the number of occurrences of program-disturbances may be relatively high when operation-data are stored. In the memory cell array 100 of the non-volatile semiconductor memory device, assuming that the memory cell 200 to be programmed is the selected memory cell, the program-disturbances may occur in the second non-selected memory cells of the second region D2 and the third region D3. In this case, the conventional method reduces a voltage for programming the selected memory cell that is applied to the first selection-line in order to prevent the program-disturbances. As a result, the selected memory cell may not be programmed. On the other hand, the method of FIG. 1 may operate to prevent the second non-selected memory cells from being programmed by applying a negative bias condition to the second non-selected memory cells (i.e., by applying a negative voltage to the second selection-lines coupled to the second non-selected memory cells) when the selected memory cell is programmed. Here, the second non-selected memory cells do not share the first selection-line with the selected memory cell. As a result, the method of FIG. 1 may improve the reliability of the non-volatile semiconductor memory device.

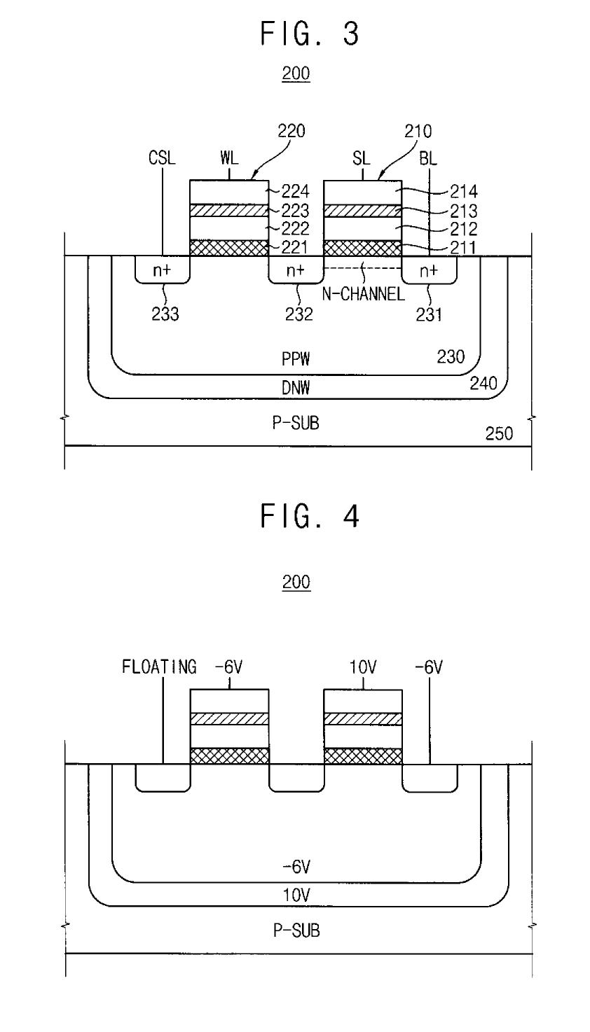

FIG. 4 is a diagram illustrating a voltage bias condition for a selected memory cell in accordance with the method of FIG. 1.

Referring to FIG. 4, it is illustrated that a voltage bias condition is applied to the selected memory cell by the method of FIG. 1. As described above, the memory cell 200 may include the memory transistor 210 and the selection transistor 220. In addition, a second terminal of the memory transistor 210 may be coupled to a first terminal of the selection transistor 220. Further, a gate terminal of the memory transistor 210 may be coupled to the first selection-line SL, a first terminal of the memory transistor 210 may be coupled to the bit-line BL, a gate terminal of the selection transistor 220 may be coupled to the word-line WL, and a second terminal of the selection transistor 220 may be coupled to the common source-line CSL. As illustrated in FIG. 4, in the selected memory cell, the second terminal of the selection transistor 220 may be floated through the common source-line CSL, the gate terminal of the selection transistor 220 may receive a negative voltage (e.g., −6V) through the word-line WL, the first terminal of the memory transistor 210 may receive a negative voltage (e.g., −6V) through the bit-line BL, and the gate terminal of the memory transistor 210 may receive a positive voltage (e.g., 10V) through the first selection-line SL. Here, a negative voltage (e.g., −6V) may be applied to the pocket P-well PPW in which the selected memory cell is located, and a positive voltage (e.g., 10V) may be applied to the deep N-well DNW in which the selected memory cell is located. As a result, the F-N tunneling phenomenon occurs in the selected memory cell, so that the selected memory cell may be programmed from an on-state to an off-state because charge is injected into the selected memory cell by the F-N tunneling phenomenon.

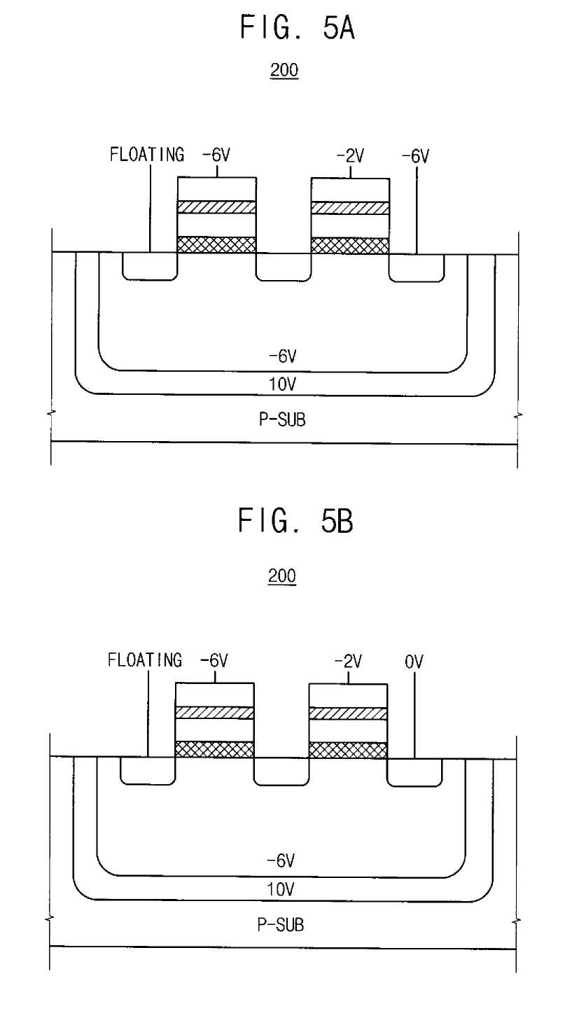

FIGS. 5A and 5B are diagrams illustrating a voltage bias condition for a second non-selected memory cell in a method of FIG. 1.

Referring to FIG. 5A, it is illustrated that a voltage bias condition is applied to the second non-selected memory cell of the second region D2 by the method of FIG. 1. As described above, the memory cell 200 may include the memory transistor 210 and the selection transistor 220. In addition, a second terminal of the memory transistor 210 may be coupled to a first terminal of the selection transistor 220. Further, a gate terminal of the memory transistor 210 may be coupled to the first selection-line SL, a first terminal of the memory transistor 210 may be coupled to the bit-line BL, a gate terminal of the selection transistor 220 may be coupled to the word-line WL, and a second terminal of the selection transistor 220 may be coupled to the common source-line CSL. As illustrated in FIG. 5A, in the second non-selected memory cell of the second region D2, the second terminal of the selection transistor 220 may be placed in a floating state through the common source-line CSL, the gate terminal of the selection transistor 220 may receive a negative voltage (e.g., −6V) through the word-line WL, the first terminal of the memory transistor 210 may receive a negative voltage (e.g., −6V) through the bit-line BL, and the gate terminal of the memory transistor 210 may receive a negative voltage (e.g., −2V) through the second selection-line SL. A negative voltage (e.g., −6V) may be applied to the pocket P-well PPW in which the second non-selected memory cell of the second region D2 is located, and a positive voltage (e.g., 10V) may be applied to the deep N-well DNW in which the second non-selected memory cell of the second region D2 is located. Since the second non-selected memory cell of the second region D2 shares, or is otherwise associated with, the bit-line BL with the selected memory cell, a negative voltage (e.g., −6V) is applied to the first terminal of the memory transistor 210 in the second non-selected memory cell of the second region D2. However, since a negative voltage (e.g., −2V) is applied to the gate terminal of the memory transistor 210 in the second non-selected memory cell of the second region D2, the occurrence of program-disturbances due to the F-N tunneling phenomenon may be mitigated or prevented in the second non-selected memory cell of the second region D2 when the selected memory cell is programmed.

Referring to FIG. 5B, it is illustrated that a voltage bias condition is applied to the second non-selected memory cell of the third region D3 by the method of FIG. 1. As described above, the memory cell 200 may include the memory transistor 210 and the selection transistor 220. In addition, a second terminal of the memory transistor 210 may be coupled to a first terminal of the selection transistor 220. Further, a gate terminal of the memory transistor 210 may be coupled to the first selection-line SL, a first terminal of the memory transistor 210 may be coupled to the bit-line BL, a gate terminal of the selection transistor 220 may be coupled to the word-line WL, and a second terminal of the selection transistor 220 may be coupled to the common source-line CSL. As illustrated in FIG. 5B, in the second non-selected memory cell of the third region D3, the second terminal of the selection transistor 220 may be placed in a floating state through the common source-line CSL, the gate terminal of the selection transistor 220 may receive a negative voltage (e.g., −6V) through the word-line WL, the first terminal of the memory transistor 210 may receive a ground voltage (e.g., 0V) through the bit-line BL, and the gate terminal of the memory transistor 210 may receive a negative voltage (e.g., −2V) through the second selection-line SL. A negative voltage (e.g., −6V) may be applied to the pocket P-well PPW in which the second non-selected memory cell of the third region D3 is located, and a positive voltage (e.g., 10V) may be applied to the deep N-well DNW in which the second non-selected memory cell of the third region D3 is located. Since a negative voltage (e.g., −2V) is applied to the gate terminal of the memory transistor 210 in the second non-selected memory cell of the third region D3, the occurrence of program-disturbances due to the electron-hole pair phenomenon may be mitigated or prevented in the second non-selected memory cell of the third region D3 when the selected memory cell is programmed.

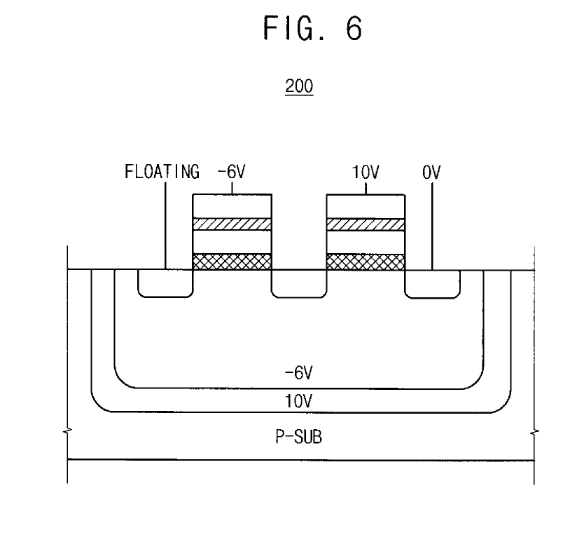

FIG. 6 is a diagram illustrating a voltage bias condition for a first non-selected memory cell in a method of FIG. 1.

Referring to FIG. 6, it is illustrated that a voltage bias condition is applied to the first non-selected memory cell of the first region D1 by the method of FIG. 1. As described above, the memory cell 200 may include the memory transistor 210 and the selection transistor 220. In addition, a second terminal of the memory transistor 210 may be coupled to a first terminal of the selection transistor 220. Further, a gate terminal of the memory transistor 210 may be coupled to the first selection-line SL, a first terminal of the memory transistor 210 may be coupled to the bit-line BL, a gate terminal of the selection transistor 220 may be coupled to the word-line WL, and a second terminal of the selection transistor 220 may be coupled to the common source-line CSL. As illustrated in FIG. 6, in the first non-selected memory cell of the first region D1, the second terminal of the selection transistor 220 may be floated through the common source-line CSL, the gate terminal of the selection transistor 220 may receive a negative voltage (e.g., −6V) through the word-line WL, the first terminal of the memory transistor 210 may receive a ground voltage (e.g., 0V) through the bit-line BL, and the gate terminal of the memory transistor 210 may receive a positive voltage (e.g., 10V) through the first selection-line SL. A negative voltage (e.g., −6V) may be applied to the pocket P-well PPW in which the first non-selected memory cell of the first region D1 is located, and a positive voltage (e.g., 10V) may be applied to the deep N-well DNW in which the first non-selected memory cell of the first region D1 is located. Since the first non-selected memory cell of the first region D1 shares the first selection-line SL with the selected memory cell, a positive voltage (e.g., 10V) is applied to the gate terminal of the memory transistor 210 in the first non-selected memory cell of the first region D1. However, since a ground voltage (e.g., 0V) is applied to the first terminal of the memory transistor 210 in the first non-selected memory cell of the first region D1, electrons are not accumulated in the floating gate of the first non-selected memory cell of the first region D1. As a result, the first non-selected memory cell of the first region D1 is prevented from becoming programmed.

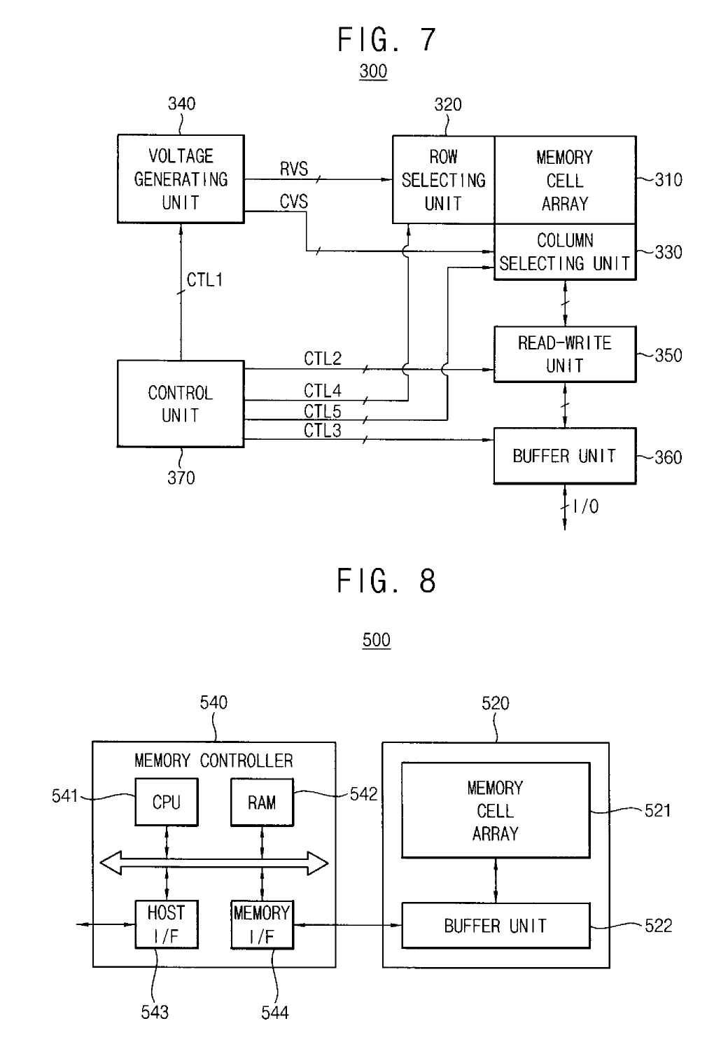

FIG. 7 is a block diagram illustrating a non-volatile semiconductor memory device employing a method of FIG. 1.

Referring to FIG. 7, the non-volatile semiconductor memory device 300 may include a memory cell array 310, a row selecting unit 320, a column selecting unit 330, a voltage generating unit 340, a read-write unit 350, a buffer unit 360, and a control unit 370. Here, the non-volatile semiconductor memory device 300 may employ the method of FIG. 1.

The memory cell array 310 may includes a plurality of memory cells. Each memory cell may include two transistors (i.e., a memory transistor and a selection transistor). Here, the memory transistor may operate for storing data, and the selection transistor may operate for selecting the memory transistor. In addition, the memory transistor and the selection transistor are coupled in series between a bit-line and a common source-line. In example embodiments, the non-volatile semiconductor memory device 300 may be 2T-FN type EEPROM device. In the memory cell array 310, a plurality of word-lines may be arranged in a row direction, a plurality of bit-lines may be arranged in a column direction, a plurality of selection-lines may be arranged in the row direction, a plurality of common source-lines may be arranged in the row direction, and each memory cell may be coupled to the word-line, the bit-line, the selection-line, and the common source-line. The row selecting unit 320 may select a row of the memory cell array 310. In addition, the row selecting unit 320 may provide voltages RVS generated by the voltage generating unit 340 to a selected row and non-selected rows of the memory cell array 310. The column selecting unit 330 may select a column of the memory cell array 310. In addition, the column selecting unit 330 may provide voltages CVS generated by the voltage generating unit 340 to a selected column and non-selected columns. The voltage generating unit 340 may generate the voltages RVS and CVS (i.e., a plurality of positive voltages, a plurality of negative voltages, a ground voltage, etc) for performing a program operation, an erase operation, and read operation of the memory cell array 310, and may provide the voltages RVS and CVS to the memory cell array 310 via the row selecting unit 320 and the column selecting unit 330.

The read-write unit 350 may operate as a sense amplifier or a write driver according to an operation mode of the non-volatile semiconductor memory device 300. For example, when the non-volatile semiconductor memory device 300 performs a read operation, the read-write unit 350 may operate as the sense amplifier for reading data from the memory cell array 310. On the other hand, when the non-volatile semiconductor memory device 300 performs a program operation, the read-write unit 350 may operate as the write driver for writing data in the memory cell array 310. The buffer unit 360 may communicate with an external device (e.g., a memory controller or a host device). That is, the buffer unit 360 may transfer data from/to the external device. The control unit 370 may control the row selecting unit 320, the column selecting unit 330, the voltage generating unit 340, the read-write unit 350, and the buffer unit 360 by providing control signals CTL1 through CTL5 to the row selecting unit 320, the column selecting unit 330, the voltage generating unit 340, the read-write unit 350, and the buffer unit 360. As described above, the non-volatile semiconductor memory device 300 employs the method of FIG. 1. Thus, when a selected memory cell is programmed in the non-volatile semiconductor memory device 300, the control unit 370 may apply a negative bias condition to non-selected memory cells that do not share a selection-line with the selected memory cell (i.e., may apply a negative voltage to selection-lines coupled to the non-selected memory cells). As a result, the program-disturbances may be prevented in the non-volatile semiconductor memory device 300, and thus reliability of the non-volatile semiconductor memory device 300 may be improved. Although a structure of the non-volatile semiconductor memory device 300 is illustrated in FIG. 7, a structure of the non-volatile semiconductor memory device 300 is not limited thereto.

FIG. 8 is a block diagram illustrating a memory system having a device of FIG. 7.

Referring to FIG. 8, the memory system 500 may include a non-volatile semiconductor memory device 520 and a memory controller 540. Here, the non-volatile semiconductor memory device 520 may correspond to the non-volatile semiconductor memory device 300 of FIG. 7.

The non-volatile semiconductor memory device 520 may include a memory cell array, a row selecting unit, a column selecting unit, a voltage generating unit, a read-write unit, a buffer unit, and a control unit. For the convenience of description, however, it is illustrated in FIG. 8 that the non-volatile semiconductor memory device 520 includes a memory cell array 521 and a buffer unit 522. As described above, since the non-volatile semiconductor memory device 520 employs the method of FIG. 1, a negative bias condition may be applied to non-selected memory cells, where the non-selected memory cells do not share a selection-line with a selected memory cell, when the selected memory cell is programmed in the non-volatile semiconductor memory device 520. As a result, the generation of program-disturbances may be mitigated or prevented in the non-volatile semiconductor memory device 520. The memory controller 540 may include a central processing unit (CPU) 541, a memory unit 542, a host interface 543, and a memory interface 544. The memory controller 540 may control the non-volatile semiconductor memory device 520, and may transfer data between external host devices and the non-volatile semiconductor memory device 520. The CPU 541 may control the memory unit 542, the host interface 543, and the memory interface 544 for processing and transferring the data. The memory unit 542 may temporarily store data provided from the external host devices, or data provided from the non-volatile semiconductor memory device 520. The host interface 543 may enable communication with the external host devices, and the memory interface 544 may enable communication with the non-volatile semiconductor memory device 520. In some example embodiments, the CPU 541 may control the non-volatile semiconductor memory device 520 via the memory interface 544. The memory system 500 may be implemented using various packages such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), thin quad flatpack (TQFP), system in package (SIP), multi chip package (MCP), wafer-level fabricated package (WFP), wafer-level processed stack package (WSP), etc.

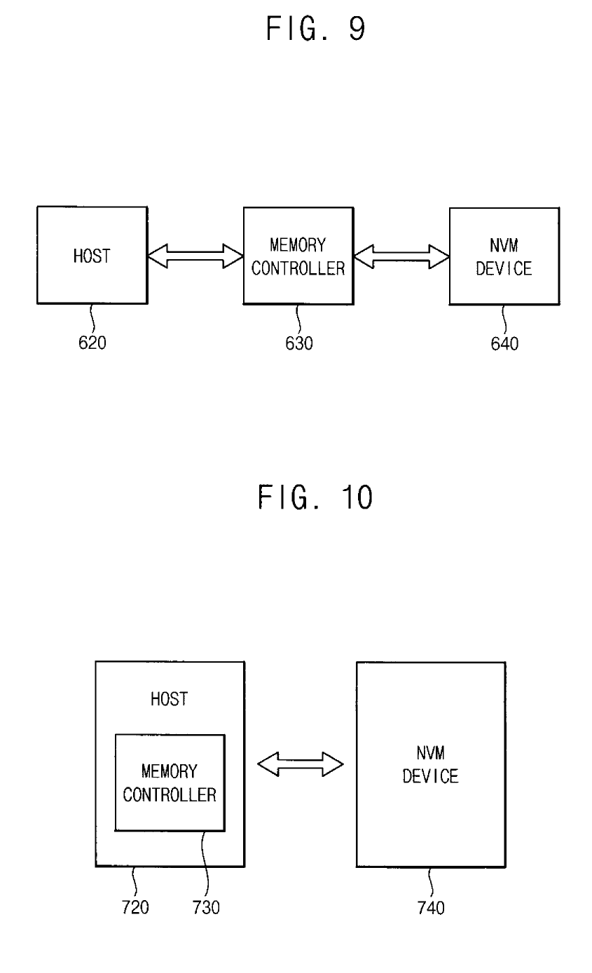

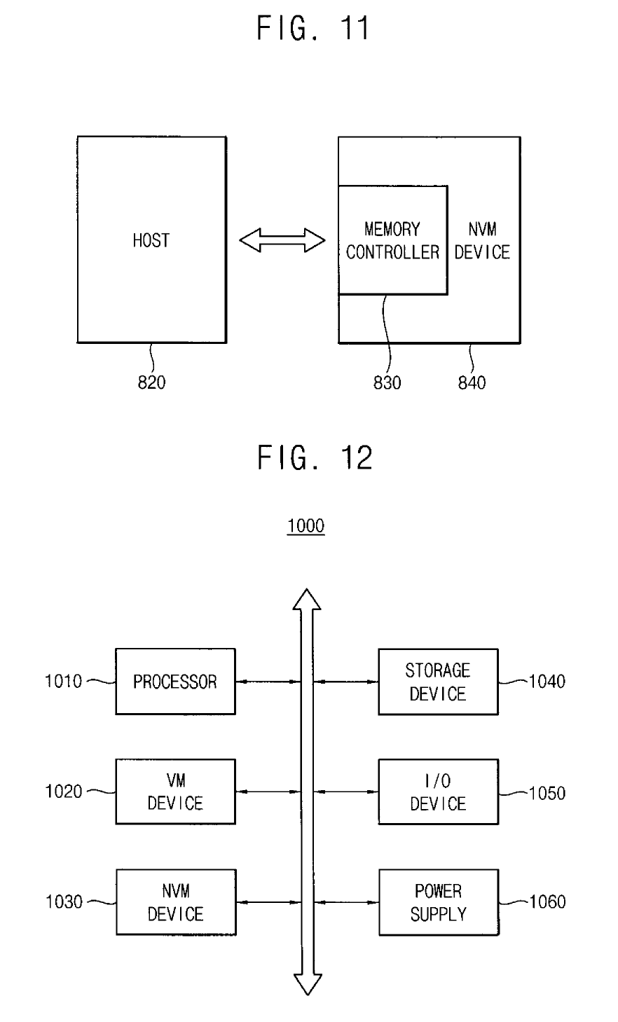

FIG. 9 is a diagram illustrating an example in which a host device is coupled to a device of FIG. 7. FIG. 10 is a diagram illustrating another example in which a host device is coupled to a device of FIG. 7. FIG. 11 is a diagram illustrating still another example in which a host device is coupled to a device of FIG. 7.

Referring to FIGS. 9 through 11, non-volatile semiconductor memory devices 640, 740, and 840 may correspond to the non-volatile semiconductor memory device 300 of FIG. 7. As illustrated in FIG. 9, the non-volatile semiconductor memory device 640 may be coupled to the host device 620 via a memory controller 630. In detail, since the memory controller 630 is implemented as a separate device from the host device 620 and the non-volatile semiconductor memory device 640, the memory controller 630 may include a CPU, a memory unit, a host interface, and a memory interface. As illustrated in FIG. 10, the memory controller 730 may be built in the host device 720, and thus the non-volatile semiconductor memory device 740 may be directly coupled to the host device 720. Since the memory controller 730 is built in the host device 720, a host processor of the host device 720 may perform the function of a CPU of the memory controller 730. As illustrated in FIG. 11, the memory controller 830 may be built in the non-volatile semiconductor memory device 840, and thus the non-volatile semiconductor memory device 840 may be directly coupled to the host device 820. Since the memory controller 830 is built in the non-volatile semiconductor memory device 840, a CPU of the memory controller 830 may perform the function of a control unit of the non-volatile semiconductor memory device 840.

FIG. 12 is a block diagram illustrating an electronic device having a device of FIG. 7.

Referring to FIG. 12, the electronic device 1000 may include a processor 1010, a volatile semiconductor memory device 1020, a non-volatile semiconductor memory device 1030, a storage device 1040, an input/output (I/O) device 1050, and a power supply 1060. Here, the non-volatile semiconductor memory device 1030 may correspond to a non-volatile semiconductor memory device 300 of FIG. 7. In addition, the electronic device 1000 may further include a plurality of ports for communicating with a video card, a sound card, a memory card, a universal serial bus (USB) device, other electronic devices, etc.

The processor 1010 may perform various computing functions. The processor 1010 may be a micro processor, a central processing unit (CPU), etc. The processor 1010 may be coupled to other components via an address bus, a control bus, a data bus, etc. Further, the processor 1010 may be coupled to an extended bus such as a peripheral component interconnection (PCI) bus. The volatile semiconductor memory device 1020 and the non-volatile semiconductor memory device 1030 may store data for operations of the electronic device 1000. For example, the volatile semiconductor memory device 1020 may correspond to a dynamic random access memory (DRAM) device, a static random access memory (SRAM) device, a mobile dynamic random access memory (mobile DRAM) device, etc. In addition, the non-volatile semiconductor memory device 1030 may correspond to a 2T-FN type EEPROM device having a memory cell array, a row selecting unit, a column selecting unit, a voltage generating unit, a read-write unit, a buffer unit, and a control unit. The storage device 1040 may correspond to a solid state drive (SSD) device, a hard disk drive (HDD) device, a CD-ROM device, etc. The I/O device 1050 may be an input device such as a key-board, a key-pad, a touch-pad, a touch-screen, a mouse, etc, and an output device such as a printer, a speaker, a display, etc. The power supply 1060 may provide a power for operations of the electronic device 1000.

The non-volatile semiconductor memory device 1030 may employ the method of FIG. 1. Thus, assuming that the non-volatile semiconductor memory device 1030 performs a program operation, a negative bias condition may be applied to non-selected memory cells, where the non-selected memory cells do not share a selection-line with a selected memory cell, when the selected memory cell is programmed in the memory cell array. Accordingly, the non-selected memory cells are not programmed because a negative voltage is applied to selection-lines coupled to the non-selected memory cells when the selected memory cell is programmed in the memory cell array. As a result, the occurrence of program-disturbances may be mitigated or prevented in the non-volatile semiconductor memory device 1030, and thus reliability of the non-volatile semiconductor memory device 1030 may be improved.

The present inventive concepts may be applied to an electronic device having a non-volatile semiconductor memory device. For example, the present inventive concepts may be applied to a computer, a laptop, a digital camera, a cellular phone, a smart phone, a smart pad, a television, a personal digital assistant (PDA), a portable multimedia player (PMP), a MP3 player, a video phone, a navigation system, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of preventing program-disturbance in a non-volatile semiconductor memory device having a plurality of memory cells, each memory cell including a selection transistor and a memory transistor that are coupled in series between a bit-line and a common source-line, where a gate terminal of the selection transistor is coupled to a word-line and a gate terminal of the memory transistor is coupled to a selection-line, the method comprising:
determining first non-selected memory cells that share a first selection-line with a selected memory cell, and second non-selected memory cells that do not share the first selection-line with the selected memory cell when the selected memory cell is selected to be programmed among the memory cells; and
applying a negative voltage to second selection-lines that are coupled to the second non-selected memory cells when the selected memory cell is programmed by applying a positive voltage to the first selection-line that is coupled to the selected memory cell.

2. The method of claim 1, wherein common source-lines that are coupled to the selected memory cell, the first non-selected memory cells, and the second non-selected memory cells are floated when the selected memory cell is programmed.

3. The method of claim 2, wherein a negative voltage that is between about −2V and about −10V is applied to a pocket P-well in which the selected memory cell, the first non-selected memory cells, and the second non-selected memory cells are located when the selected memory cell is programmed.

4. The method of claim 3, wherein a negative voltage of about −6V is applied to the pocket P-well in which the selected memory cell, the first non-selected memory cells, and the second non-selected memory cells are located when the selected memory cell is programmed.

5. The method of claim 3, wherein a positive voltage that is between about 6V and about 14V is applied to a deep N-well that is formed under the pocket P-well when the selected memory cell is programmed.

6. The method of claim 5, wherein a positive voltage of about 10V is applied to the deep N-well that is formed under the pocket P-well when the selected memory cell is programmed.

7. The method of claim 5, wherein a negative voltage that is between about −2V and about −10V is applied to word-lines that are coupled to the selected memory cell, the first non-selected memory cells, and the second non-selected memory cells when the selected memory cell is programmed.

8. The method of claim 7, wherein a negative voltage of about −6V is applied to the word-lines that are coupled to the selected memory cell, the first non-selected memory cells, and the second non-selected memory cells when the selected memory cell is programmed.

9. The method of claim 7, wherein the negative voltage that is applied to the second selection-lines is determined to be between about −1V and about −3V when the selected memory cell is programmed.

10. The method of claim 9, wherein the negative voltage that is applied to the second selection-lines is determined to be about −2V when the selected memory cell is programmed.

11. The method of claim 9, wherein the positive voltage that is applied to the first selection-line is determined to be between about 6V and about 14V when the selected memory cell is programmed.

12. The method of claim 11, wherein the positive voltage that is applied to the first selection-line is determined to be about 10V when the selected memory cell is programmed.

13. The method of claim 11, wherein a negative voltage that is between about −2V and about −10V is applied to a first bit-line that is coupled to the selected memory cell when the selected memory cell is programmed.

14. The method of claim 13, wherein a negative voltage of about −6V is applied to the first bit-line that is coupled to the selected memory cell when the selected memory cell is programmed.

15. The method of claim 13, wherein the program-disturbances due to an F-N tunneling phenomenon are prevented in the second non-selected memory cells that share the first bit-line with the selected memory cell when the selected memory cell is programmed, and
wherein the program-disturbances due to an electron-hole pair phenomenon are prevented in the second non-selected memory cells that do not share the first bit-line with the selected memory cell when the selected memory cell is programmed.

16. A method of programming a non-volatile memory device, the device including a plurality of memory cells, each memory cell including a selection transistor and memory transistor arranged in series between a bit line and a common source line of the memory device, a gate terminal of the selection transistor being coupled to a word line of the device and a gate terminal of the memory transistor being coupled to a selection line of the device, comprising, during a programming operation of a selected memory cell by applying a positive voltage to a first selection line that is coupled to the selected memory cell, applying a negative bias condition to non-selected memory cells by applying a negative voltage to second selection lines that are respectively coupled to the non-selected memory cells.

17. The method of claim 16 wherein non-selected memory cells are associated with a same bit line as the selected memory cell.

18. The method of claim 16 further comprising applying a negative voltage to the bit line that is associated with the selected memory cell, and applying a GND voltage to bit lines that are unassociated with the selected memory cell.

19. The method of claim 16 wherein the negative voltage is in a range between about −1V and −3V.

20. The method of claim 16 wherein the negative voltage is about −2V.
